(19) United States
(12) Patent Application Publication
(10) Pub. No.: US 2025/0357268 A1
(43) Pub. Date: Nov. 20, 2025

(54) Semiconductor Device Package with Thermal Module

(71) Applicant: Taiwan Semiconductor Manufacturing Company, Ltd., Hsinchu (TW)

(72) Inventors: Sing-Da JIANG, Hsinchu (TW); Po-Yao LIN, Hsinchu County (TW); Tsunyen WU, Hsinchu County (TW); Shih-Wei LIU, Hsinchu (TW); Kathy Wei YAN, Hsinchu (TW); Jun HE, Hsinchu County (TW)

(21) Appl. No.: 19/283,439

(22) Filed: Jul. 29, 2025

Related U.S. Application Data
(63) Continuation of application No. 18/467,200, filed on Sep. 14, 2023.
(60) Provisional application No. 63/503,805, filed on May 23, 2023.
(60) Provisional application No. 63/507,611, filed on Jun. 12, 2023.

(51) Int. Cl. H01L 23/473; H01L 23/00; H01L 23/24; H01L 23/40; H01L 23/62; H01L 25/00; H01L 25/065

(52) U.S. Cl. CPC H01L 23/473; H01L 23/24; H01L 23/4006; H01L 23/62; H01L 24/32; H01L 25/0655; H01L 25/50; H01L 2023/4087; H01L 24/16; H01L 24/73; H01L 2224/16225; H01L 2224/32245; H01L 2224/73253; H01L 2225/065; H01L 2924/16235; H01L 2924/1659

(57) ABSTRACT

A device package provides for thermal considerations of a semiconductor die(s) through providing a thermal module. A substrate including an IC die disposed on the substrate is positioned between an upper plate and a lower plate of the thermal module. Heat pipes connect the upper plate and the lower plate. The thermal module allows for heat dissipation paths from the lower as well as upper plate. In some implementations, a liquid cooling plate is positioned between the substrate and the upper plate of the thermal module.

### PRIORITY DATA

This application is a continuation of U.S. patent application Ser. No. 18/467,200 filed Sep. 14, 2023, which claims priority to U.S. Provisional Patent Application Ser. No. 63/507,611 filed Jun. 12, 2023 and U.S. Provisional Patent Application Ser. No. 63/503,805 filed May 23, 2023 the entire disclosures of each of which is hereby incorporated herein by reference.

### BACKGROUND

The electronics industry has experienced an ever-increasing demand for smaller and faster semiconductor devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Operation of semiconductor devices as they become more powerful can require tuning of their supply voltages and optimization of surrounding conditions. For example, different voltages may be provided to different circuit blocks by implementing a voltage regulator module (VRM) corresponding to a given circuit block. Additionally, as semiconductor devices become more powerful, they generate more heat and may benefit from application of cooling techniques.

Existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device package, in accordance with some embodiments of the present disclosure;

FIG. 2A is a cross-sectional view of the semiconductor device package along the A-A line in FIG. 1, in accordance with some embodiments of the present disclosure;

FIG. 2B is a fragmentary cross-sectional view of a portion of the semiconductor device package of FIG. 2A, in accordance with some embodiments of the present disclosure;

FIG. 2C is a top view of the semiconductor device package along the line A1-A1 in FIG. 2B, in accordance with some embodiments of the present disclosure;

FIG. 3A is a cross-sectional view of another embodiment of a semiconductor device package corresponding to the A-A line in FIG. 1, in accordance with some embodiments of the present disclosure;

FIG. 4 is a flow chart of an embodiment of an assembly method of a semiconductor device package, according to some embodiments of the present disclosure.

FIGS. 5A, 5B, 5C, and 5D are perspective views of an embodiment of an assembly method corresponding to the flowchart of FIG. 4, in accordance with some embodiments of the present disclosure;

FIG. 6A is a perspective view of another embodiment of a semiconductor device package omitting a liquid cooling system, in accordance with some embodiments of the present disclosure;

FIG. 6B is a cross-sectional view of one embodiment of the semiconductor package of FIG. 6A corresponding to the C-C line in FIG. 6A, in accordance with some embodiments of the present disclosure;

FIG. 7 is a cross-sectional view of one embodiment of the semiconductor package of FIG. 6A corresponding to the C-C line in FIG. 6A, in accordance with some embodiments of the present disclosure;

FIG. 8A is a cross-sectional view of one embodiment of a semiconductor device package according to FIG. 1, in accordance with some embodiments of the present disclosure;

FIG. 8B is a top view of the semiconductor device package along the line D-D in FIG. 8A, in accordance with some embodiments of the present disclosure; and

FIG. 9 is a flow chart illustrating an embodiment of a method of dissipating heat using a semiconductor device package according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

In some implementations, high performance packages are provided to accommodate functional and thermal needs of semiconductor devices. For example, the package may accommodate multiple die, voltage regulator modules integrated on-package, and thermal dissipation features. While thermal elements such as heatsinks and fan modules can dissipate heat from the semiconductor device environment, the dissipation efficiency and effectiveness can raise challenges. For example, as device needs require modules be positioned at different regions of the package, it may be difficult to dissipate heat using heatsinks that may be located a distance from the heat generating device component. Thus, elements of the present disclosure in some implementations provide for multiple heat dissipation paths for a semiconductor device.

One, non-limiting example of a semiconductor device component (e.g., integrated circuit die) that may benefit from heat dissipation is a voltage regulator module. A voltage regulator module(s) can be integrated on-package with other integrated circuit devices in various configurations. To supply the voltages to the various circuit blocks of the IC devices, a separate voltage regulator module (VRM) corresponding to a given circuit block may be used. Due to the power dissipated in operation, and the technology used to fabricate the VRMs, the VRMs may be disposed separately from a circuit block on the integrated circuit that the VRMs power. When the VRMs are fabricated as separate integrated circuits, and the power is delivered by an electrical wiring connection between the VRM and the integrated circuit. If the electrical wiring connection is long, resistance cause power losses. Therefore, the VRM benefits from positioning as close as possible to the circuit block of the integrated circuit driven by the VRM. For example, in some implementations such as illustrated herein, the VRM are positioned below the IC die on an opposing side of a substrate, which includes routing to couple the VRM and IC die. Such positioning may also provide obstacles to dissipating the heat generated by the VRM. Without sufficient dissipation of this heat, the VRM may overheat and risk failing. Thus, the present disclosure accommodates in some implementations dissipating heat from the VRM surroundings (as well as the IC surroundings).

While the present disclosure provides exemplary semiconductor devices including integrated circuit (IC) die and VRM provided on opposing surfaces of a substrate, this configuration is exemplary only and not limiting beyond what is explicitly recited in the claims that follow. The thermal modules discussed herein can apply to various semiconductor devices including those including other components, and other configurations of said components.

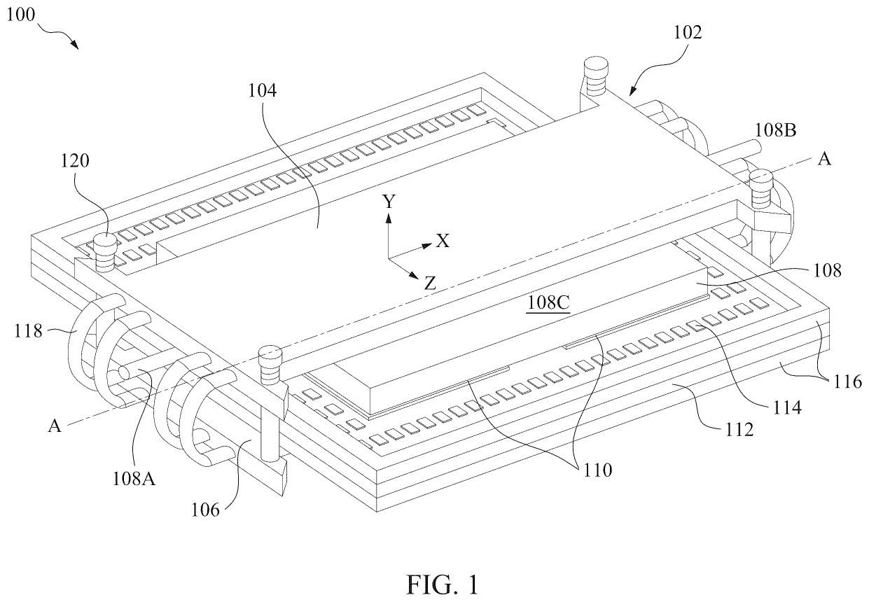

Referring to FIG. 1, illustrated is a perspective view of a semiconductor device package 100 including a thermal module according to one or more aspects of the present disclosure. The package 100 includes a thermal module 102. The thermal module 102 is a double-sided thermal module providing a thermal dissipation path from a top side and a thermal dissipation path from a bottom side of the semiconductor devices provided in the package 100. In doing so, the thermal module 102 comprises a “sandwich” style configuration for the thermal module as it has a top plate 104 and a bottom plate 106 spaced apart to accommodate the semiconductor device(s) between the plates 104, 106. The thermal module 102 may be used alone, or in conjunction with other thermal components such as a liquid cooling system 108, discussed below.

The semiconductor device included in the package may provide any number of integrated circuit die or other components. In the illustrated embodiment, the package 100 includes a substrate 112 upon which integrated circuit (IC) die 110 (also referred to as chips) are disposed. In an embodiment, the IC die 110 are chip-on-wafer (CoW) configuration. CoW devices include individual chips bonded through interconnects, such as microbumps) to an interposer substrate. The interposer substrate may be substrate 112, or another substrate formed over the substrate 112 in a stacked configuration. One or more chips may be stacked and configured as the IC die 110. A plurality of chiplets 114 may also be provided on the substrate 112. The chiplets 114 may be an integrated circuit chip with a specific functionality. The chiplets 114 may provide different functionality that one another. Any number of IC die 110, chiplets 114, passive components, and/or other components may be provided on the substrate 112. In some implementations, various components including IC die 110 are provided on a backside of the substrate 112. In some implementations, including as discussed below, VRM are disposed on the backside of the substrate 112 in addition to or in lieu of IC die 110.

One or more rings 116 are provided in the package 100. In an embodiment, a ring is aligned with at least one edge of the substrate 112 and encases the IC die 110. The substrate 112 provides electrical and/or structural support for the IC die 110 and other components. The substrate 112 may include silicon and may include electrical routing in the form of a multi-layer interconnect (MLI), through substrate vias, and the like. In some implementations, the substrate 112 is an interposer. The substrate 112 may extend beyond the thermal module 102 in at least one direction (e.g., z-direction of FIG. 1).

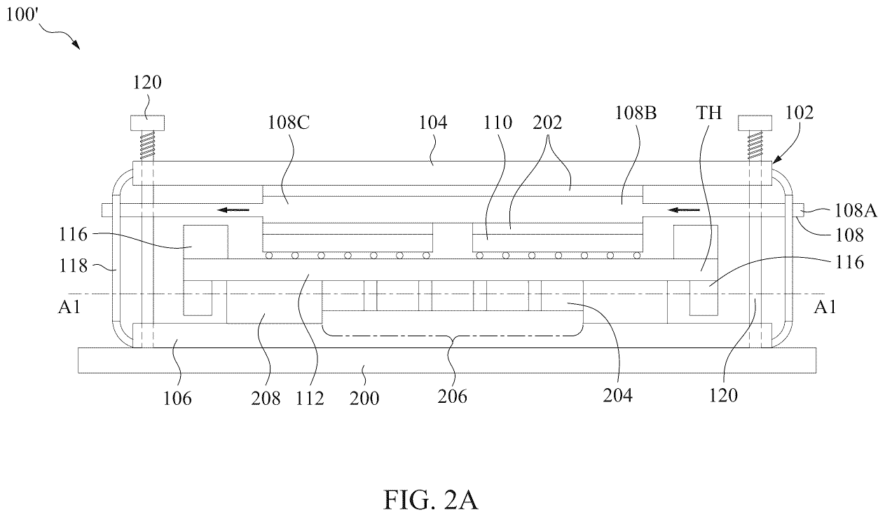

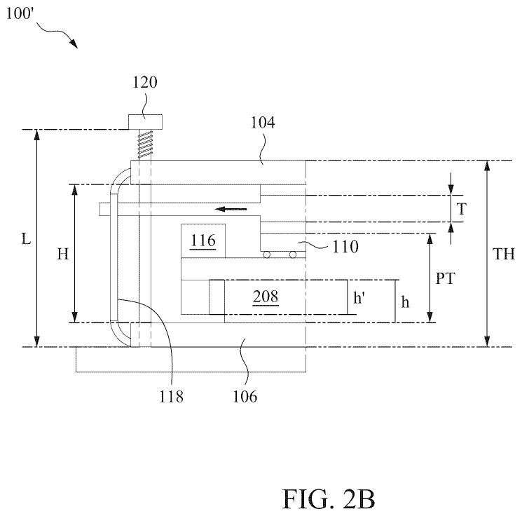

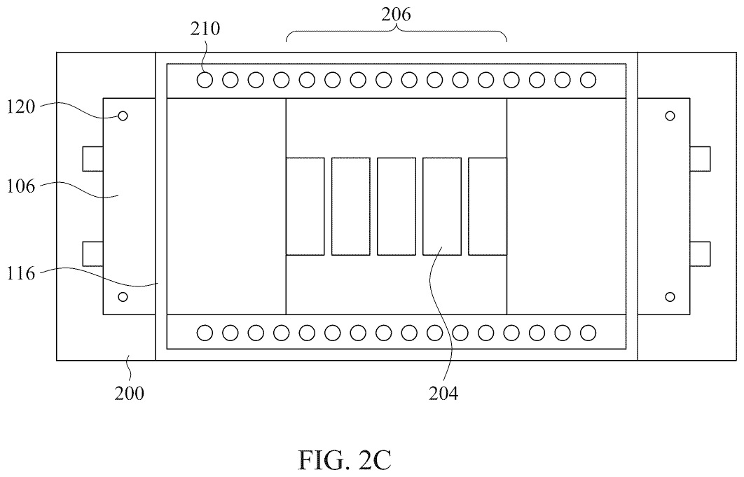

The thermal module 102 comprises a “sandwich” style thermal module component having a top plate 104 and a bottom plate 106, between which the substrate 112 including IC die 110 are disposed. In some implementations, the sandwich style thermal module component provides multiple heat dissipation paths. One heat dissipation path includes the bottom plate 106 providing a heat dissipation path for semiconductor devices (e.g., VRM components as discussed below) attached to a bottom side of the substrate 112 (see FIG. 2A). The sandwich style thermal module component includes another heat dissipation path including the top plate 104 providing a heat dissipation path for semiconductor devices (e.g., integrated circuit die 110 and/or other components) attached to a top side of the substrate 112. The components (e.g., IC die 110) on a top surface of the substrate 112 are thermally coupled to the top plate 104; the components (e.g., IC die 110, VRM) on a bottom surface of the substrate 112 are thermally coupled to the bottom late 106. In some implementations, the thermal coupling is provided by a physical interface between the devices and the plates, or contiguous thermally conductive path through materials (e.g., thermal interface material and/or other heat conducting structures) between the devices the plates. The top plate 104 and the bottom plate 106 are referred to as cold plates suitable for conduction and dissipation of heat. In some implementations, the top plate 104 and/or the bottom plate 106 are of a heat conducting material, are liquid-filled, and/or provide other suitable heat conduction features.

In the thermal module 102, the top plate 104 and the bottom plate 106 are connected by at least one heat pipe 118. In the illustrated embodiment of FIG. 1, eight heat pipes 118 connect the top plate 104 and the bottom plate 106. The heat pipes 118 are U-shaped heat pipes contiguously extending from the top plate 104 to the bottom plate 106. While four heat pipes 118 are illustrated on each end of the package 100, any number of heat pipes 118 may be included. In some implementations, the heat pipes 118 allow the flow of heat from the bottom plate 106 to the top plate 104, which is also cooled by the adjacent liquid cooling plate 108 in some implementations.

The top and bottom plates 104 and 106 may be comprised of metal. In an embodiment, the top and bottom plates 104 and 106 are comprised of a metal suitable for conducting heat such as aluminum, copper, gold, steel, alloys, or the like. In an embodiment, one or more of the top and bottom plates 104 and 106 are filled with liquid such as a coolant and/or water. In some implementations, the liquid of the top and bottom plates 104 and/or 106 may be substantially similar to the liquid of the liquid cooling system 108, discussed below. The liquid may be comprised of a material selected for its high enthalpy of vaporization.

The thermal module 102 also secures the top plate 104 and the bottom plate 106 by a fastening mechanism 120. The fastening mechanism 120 may be a spring screw. Four fastening mechanisms 120 are illustrated, however, other configurations and number of fasteners may be provided. The fastening mechanisms 120 serve to clamp the thermal module into its sandwich configuration. The fastening mechanism 120 (e.g., spring screw) may provide a suitable force to sandwich the thermal module (and plates 104/106) to provide a physical interface of the IC die 110 and the thermal interface material (TIM) disposed thereon (illustrated below in FIG. 2A) and the plate 104. The fastening mechanism (e.g., spring screw) may also provide a suitable force to sandwich the thermal module (and plates 104/106) to provide a physical interface of the components disposed on the bottom surface of the substrate 112 (and the thermal interface material (TIM) disposed thereon (illustrated below in FIG. 2A)) and the plate 106. The physical interfaces provide for a thermal coupling of the devices and the respective plates 104/106.

The package 100 also includes a liquid cooling system 108 disposed in the thermal module 102. The liquid cooling system 108 brings additional heat dissipation to the devices from a top-side of the package 100. In an implementation, the liquid cooling system 108 serves to dissipate heat from the integrated circuit die 110 on the top surface of the substrate 112. In some implementations, the liquid cooling system 108 serves to provide heat dissipation to the top plate 104 (including, e.g., heat transferred by heat pipes 118 from the bottom plate 106).

In some implementations, the package 100 includes one of the sandwich thermal module 102 or the liquid cooling system 108. In some implementations, the package 100 includes both the sandwich thermal module 102 and the liquid cooling system 108, as illustrated in FIG. 1. The liquid cooling system 108 includes an inlet 108A and an outlet 108B for a coolant. In some implementations, the coolant enters the inlet 108A as a liquid. The center portion 108C may include a plate having a passage for the coolant disposed therein. In an embodiment, the coolant is a material having a high enthalpy of vaporization. In some implementations, the coolant is water. Other examples include deionized water, glycol/water solutions, fluorocarbons, and/or other suitable coolants. The coolant may exit the package 100 through outlet 108B. In some implementations, the coolant may be at least partially in vapor form when exiting outlet 108B.

In some implementations, the inlet 108A and/or the outlet 108B are connected to liquid cooling systems associated with other semiconductor devices or semiconductor device packages that may be disposed on a same system board as the package 100. In such an implementation, the coolant may be shared amongst components.

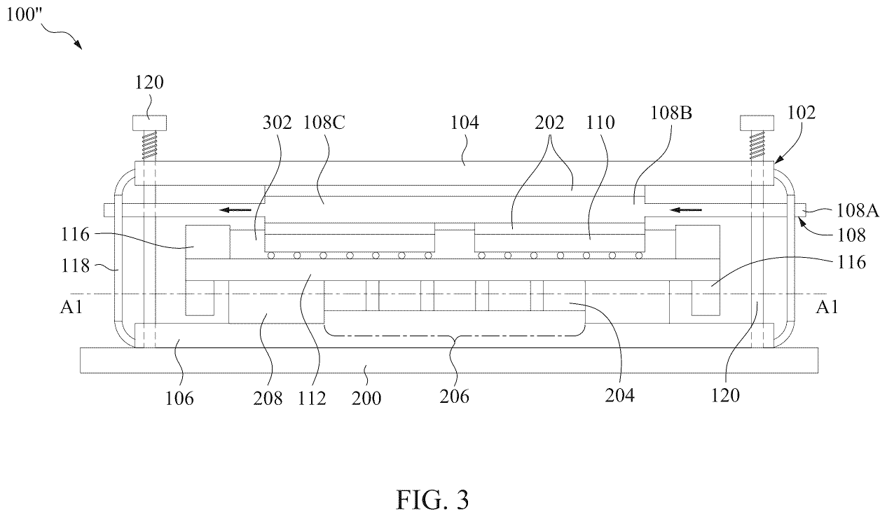

Further details of aspects of embodiments of the package 100 are also described in the following views illustrated as package 100′ and 100″ in FIGS. 2A, 2B and 2C and FIG. 3 respectively. FIGS. 2A, 2B, and 2C illustrate a package 100′ according to one or more aspects of the present disclosure. FIGS. 2A and 2B are a cross-sectional views of the package 100′ along a cut A-A of FIG. 1, and FIG. 2C provides a corresponding top view, along a cut A1-A1 in FIG. 2A.

As illustrated in FIG. 2A, the semiconductor device package 100′ is mounted on a substrate 200. The substrate 200 may be a printed circuit board (PCB) substrate. In some implementations, the substrate 200 is a system board having the package 100′ along with other packages and integrated circuits such as CPUs, memory devices, processors, and/or other suitable components. One or more of the components also provided on the substrate 200 may implement the thermal module 102. The substrate 200 may be installed in a server, information handling system, and/or other application. It is noted that only a fragment of the substrate 200 is shown.

The package 100′ includes components similar to as discussed above with reference to the package 100 in FIG. 1 and like reference numbers are used to refer to like components. The package 100′ illustrates the thermal module 102 as a sandwich-type thermal module including a top plate 104 and a bottom plate 106 encasing a plurality of IC die 110 disposed on a substrate 112. A liquid cooling system 108 is provided between the top plate 104 and the IC die 110. The liquid cooling system 108 includes an inlet 108A for providing a coolant; and an outlet 108B for releasing the coolant after it passes through passages of the center region 108C. In some implementations, the inlet 108A is connected to a plate of an adjacent package 100, and/or the outlet 108B is connected to a plate of an adjacent package 100. In other words, coolant passing through the passages of the liquid cooling system 108 can be delivered to a liquid cooling system 108 of another device or devices on the board 200.

The IC die 110, for example, a chip-on-wafer configured chip, is connected to the substrate 112 by conductive bumps such as solder balls. However, other interconnections are possible. The package 100′ is also connected to the system substrate 200 both mechanically and electrically (not shown).

A thermal interface material (TIM) 202 is included in the package 100′. The TIM 202 provides a physical and thermal coupling between two components. In an embodiment, the TIM 202 fills a space between the IC die 110 and the liquid cooling system 108. In an embodiment, the TIM 202 fills a space between the top plate 104 of the thermal module 102 and the liquid cooling plate 108C. TIM 202 thermally couples and provides a heat dissipation path between the top plate 104 and the liquid cooling plate 108C. In an embodiment, the TIM 202 fills a space between the liquid cooling plate 108C and the IC die 110 on the substrate 112. TIM 202 thermally couples and provides a heat dissipation path between the IC die 110 and the liquid cooling plate 108C. The TIM 202 may be a gel, glue, tape comprising a compound suitable for transfer of heat. TIM may be a material (e.g., polymer) having a good thermal conductivity (Tk). In addition to a polymer, or a metal filled polymer, metallic-based or solder-based material comprising silver, indium paste, or the like may be provided.

As illustrated in FIG. 2A, a plurality of voltage regulator modules (VRM) 204 are formed on a backside of the substrate 112. The VRM 204 are one exemplary type of IC die (chip) 110. In an embodiment, the VRM 204 are interconnected through traces in the substrate 112 to one or more of the IC die 110 also disposed on the substrate 112. Five VRM 204 and two IC chips 110 are illustrated, however the present disclosure extends to any number and any configuration of semiconductor devices.

The VRM 204 are physically and electrically connected to a bottom surface of the substrate 112. The VRM 204 are also physically connected to a top surface of the bottom plate 106 of the thermal module 102. The VRM 204 may be connected directly to the bottom plate 106. In another embodiment, the VRM 204 may be connected to the bottom plate 106 through thermal interface material (TIM) such as the TIM 202. That is, a TIM 202 may interpose each VRM 204 and bottom plate 106. Either through the TIM or directly, the VRM 204 are thermally coupled to the bottom plate 106 of the thermal module 102.

In an embodiment, the bottom plate 106 includes a raised portion 206 having an upper surface nearer the substrate 112 than an end portion adjacent the raised portion 206. In an embodiment, the raised portion 206 has a thickness greater than the edge portions of the plate 106. In some implementations, the thickness of the raised portion 206 of the plate 106 is between 10% and 100% greater than the edge regions. As illustrated in FIG. 1, the upper plate 104 and/or the lower plate 106 have a shape in a top view of a substantially rectangular midportion and an end region of said rectangular shape includes an increased width at a region for receiving the fasteners 120. The end regions may include a tapered sidewall from the rectangular shaped center region to a terminal end of the plate. The raised portion 206 may extend the width of the plate 106 (see FIG. 2C).

A connector material 208 is disposed adjacent and surrounding the VRM 204. In an embodiment, the connector material 208 extends from an upper surface of the bottom plate 106 (including an edge region and raised portion 206) to a bottom surface of the substrate 112. In an embodiment, the connector 208 may be a glue, molding compound, or other material.

A ring 116 surrounds the components (IC die 110, VRM 204) on the substrate 112. The ring 116 disposed on a top surface of the substrate 112 is referred to as a frontside ring, and the ring 116 disposed on a back surface of the substrate 112 is referred to as a backside ring. In an embodiment, as illustrated in package 100′, a gap is provided between the frontside ring 116 and the liquid cooling system 108. And another gap is present between the backside ring 116 and the bottom plate 106 of the thermal module 102. In other embodiments, one or more of these gaps are filled with thermally conductive material(s) or omitted. In some implementations, the frontside and backside rings 116 are substantially similar in shape from a top view (e.g., rectangular). In some implementations, a frontside ring 116 is thicker than the backside ring 116 (in an x-direction), but of a similar shape (e.g., rectangular). The rings 116 may be aligned with a terminal edge of the substrate 112. The rings 116 may be comprised of metal suitable for thermal conduction to assist in the heat dissipation from surroundings of the VRM 204 and/or IC die 110. Example metal materials for the rings 116 include aluminum, copper, alloys, and the like.

FIG. 2B illustrates a fragmentary, cross-sectional view of a portion of the package 100′ to illustrate relative dimensions thereof. The package 100′ has a total thickness of TH. The fastener 120 (e.g., spring screw) has a length of L. A distance between a bottom of the top plate 104 and the bottom plate 106 of the thermal module 102 is H. A height of the backside ring 116 is h′. A thickness of the liquid cooling plate 108 is T. A package thickness is PT. In an embodiment, H is ≥T+PT. In an embodiment, L≥TH. In an embodiment, h′≤a thickness of the connector plus the bottom plate 106 thickness. The connector 208 has a height h, which is greater than or equal to the backside ring 116 height h′.

FIG. 2C illustrates a cross-sectional view taken through A1-A1 of FIG. 2A of the package 100′ in the z-direction. The connector 208 is omitted for ease of illustration. FIG. 2C illustrates the backside ring 116, the VRMs 204, the bottom plate 106 and the portion of the system board 200. A plurality of fasteners 120 are provided, one on each corner of the bottom plate 106. Additionally, a plurality of connectors 210 are arranged adjacent to a terminal edge of the plate 106. The connectors 210 may be arranged in one or more rows. In an embodiment, the connectors 210 are pins.

It is noted that in an embodiment of the package 100′ neither a fan nor a heat sink is included in the package 100′. In some implementations, the thermal module 102 is sufficient to provide multiple heat dissipation paths for the IC die 110 and the VRM 204 to mitigate a need for such additional components.

FIG. 3 is illustrative of a cross-section of an embodiment of a package 100″. The package 100″ is an embodiment of the package 100 discussed above with reference to FIG. 1. The package 100″ is also substantially similar to the package 100′ discussed above with reference to FIGS. 2A, 2B, and 2C. The package 100″ differs by illustration of a molding compound 302 disposed on a top surface of the substrate 112 and surrounding the IC die 110. The molding compound 302 may be included in any one of the embodiments of the present disclosure.

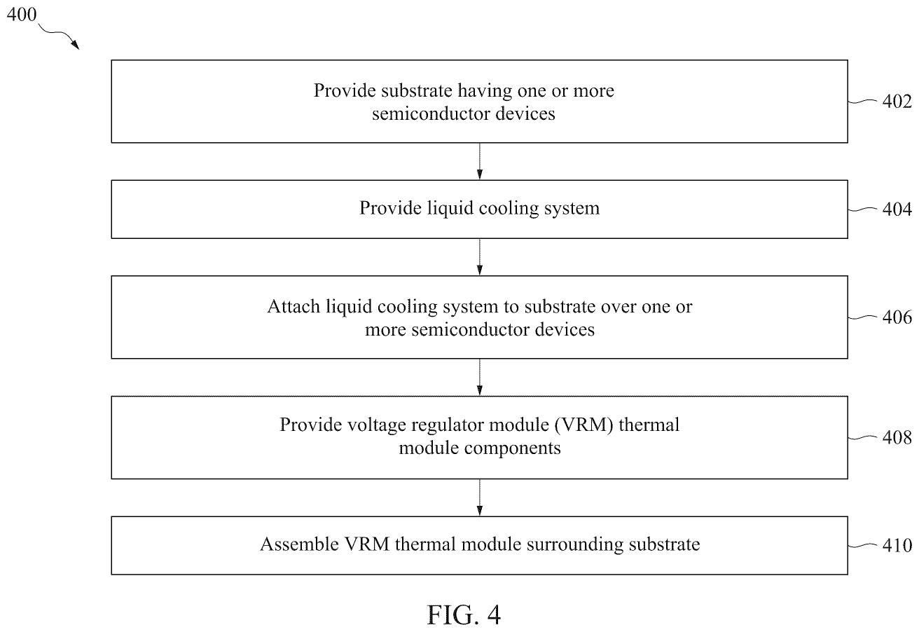

One or more of the aspects of the embodiments of the semiconductor device packages discussed above, packages 100, 100′, 100″, may be manufactured and/or assembled according to aspects of a method 400 illustrated in FIG. 4. The method 400 includes assembly of a thermal module substantially similar to the thermal module 102 discussed above.

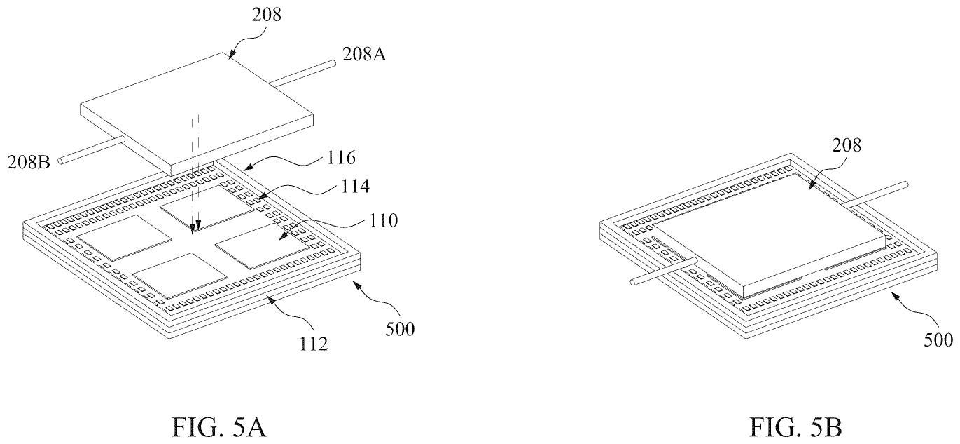

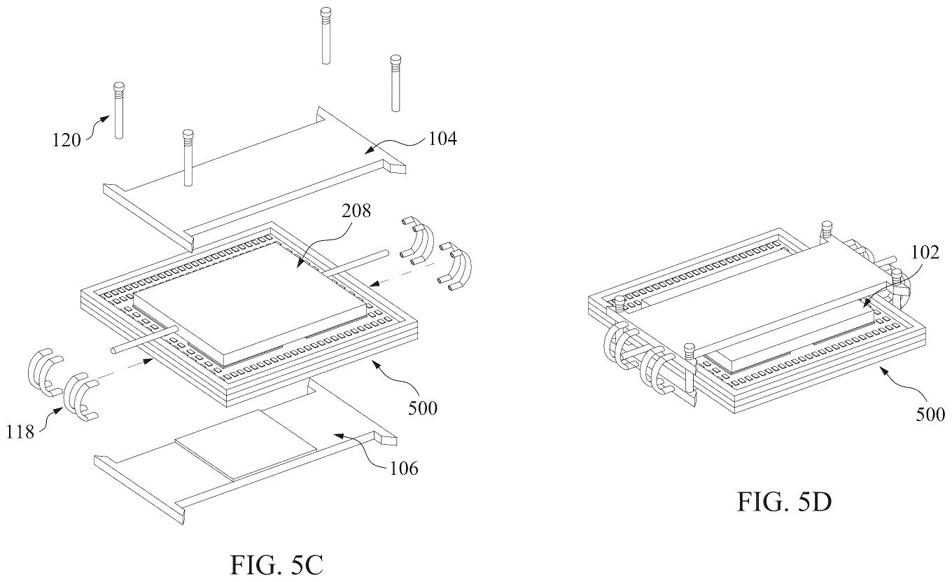

The method 400 begins at block 402 where a substrate having one or more semiconductor devices such as ICs disposed thereon is provided. In an embodiment, a substrate having a plurality of IC device such as chip-on-wafer device, VRM, chiplets, passive devices, other semiconductor devices, and/or other semiconductor devices is provided. The IC devices (including chiplets) may be mounted to a top surface and/or a bottom surface of the substrate. An example of a substrate provided in block 402 is the substrate 112 having a plurality of IC die 110 disposed thereon. Referring to the example of FIG. 5A, FIG. 5A illustrates a semiconductor device 500 having a substrate 112, a plurality of IC die 110, a plurality of chiplets 114, each which may be substantially similar to as discussed above. The semiconductor device 500 includes a two by two (2×2) array of IC die 110 on a frontside surface of the substrate 112. However, other configurations including any number and position of IC die 110 are possible. In an embodiment, components such as VRM are disposed on a backside of the substrate 112.

The method 400 then proceeds to block 404 where a liquid cooling system is provided. In an embodiment, the liquid cooling system includes a plate suitable for receiving and expelling a coolant to provide for cooling of a semiconductor device. In an embodiment, the liquid cooling system includes an inlet, a plate center portion having a passage for coolant received in the inlet, and an outlet for removing the coolant, now spent, from the plate. An example of the liquid cooling system provided in block 404 is the liquid cooling system 108 discussed above with reference to FIGS. 1-3. Referring to the example of FIG. 5A, a liquid cooling system 108 is provided. The liquid cooling system 108 may be substantially similar to as discussed above including providing an inlet 108A and outlet 108B for coolant, and a center plate portion 108C having passages for said coolant.

The method 400 then proceeds to block 406 where the liquid cooling system of block 404 is attached to the semiconductor device of block 402. In an embodiment, the liquid cooling system may be mounted such that it is thermally coupled to a semiconductor device. In some implementations, a TIM is positioned between the IC die of the semiconductor device and the liquid cooling system. The liquid cooling system is thermally coupled to the semiconductor device, either directly or through the TIM. Referring to the example of FIG. 5B, the liquid cooling system 108 is positioned over and thermally coupled to the IC die 110 of the semiconductor device 500. In an embodiment, the liquid cooling system extends over the IC die 110 but does not extend to an edge of the semiconductor device 500. As illustrated, a peripheral region (e.g., containing chiplets 114) may be exposed after mounting the liquid cooling system 108.

The method 400 proceeds to block 408 where components of a thermal module including one or more voltage regulator modules is provided. In an embodiment, the thermal module may be substantially similar to the module 102 discussed above with reference to FIGS. 1-3. In an embodiment, as illustrated in FIG. 5C, the components provided may include a lower plate 106 and an upper plate 104. A plurality of heat pipes 118 are provided, which are configured to connect the lower plate 106 and the upper plate 104. A plurality of fasteners 120 such as spring screws are provided and configured such that the fasteners (e.g. spring screws) are suitable to extend the thickness of the thermal module 102 when assembled.

In an embodiment, the lower plate 106 is configured to have a raised portion corresponding to components disposed on a bottom of substrate 112. For example, in an embodiment, the lower plate 106 has a raised portion corresponding to a region of VRM disposed on the backside of the substrate 112.

Referring to the example of FIG. 5D, a thermal module 102 is assembled by providing the semiconductor device 500 and liquid cooling assembly 108 between the upper plate 104 and the lower plate 106 of the thermal module. Fasteners 120 secure the module 502 in the sandwich configuration. The method 400 may continue to include mounting the assembled package on a system board such as the substrate 200 discussed above.

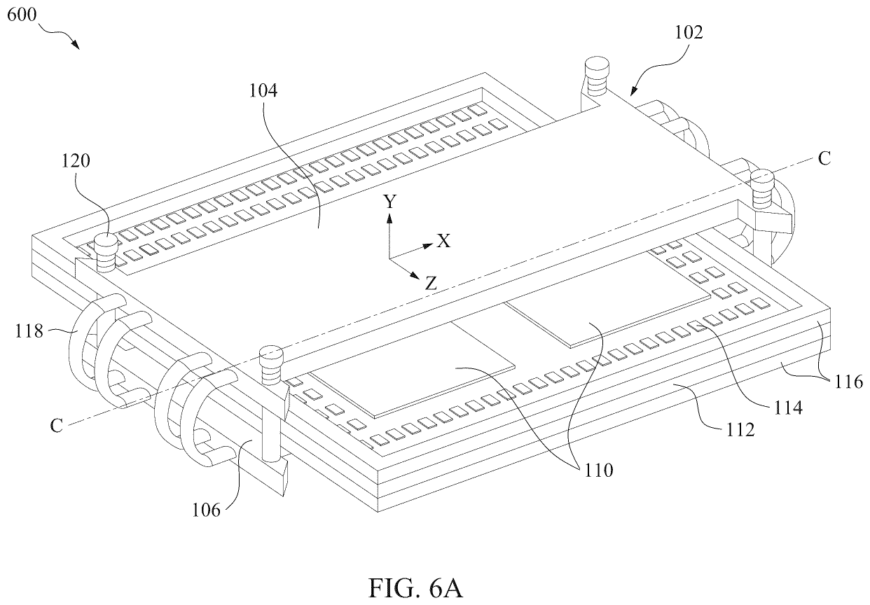

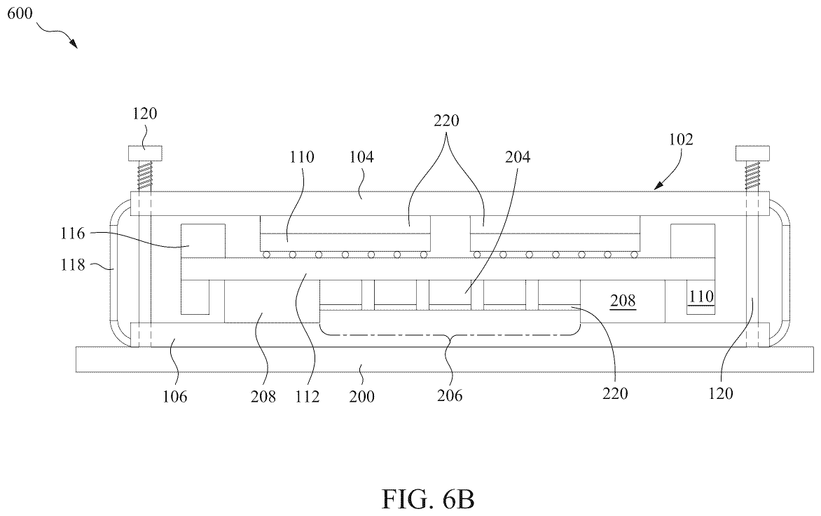

Referring to FIG. 6A, illustrated is a perspective view of another semiconductor device package 600 including a thermal module according to one or more aspects of the present disclosure. Further details of aspects of the package 600 are also described in the cross-sectional view of FIG. 6B along line C-C of FIG. 6A. The package 600 includes a thermal module 102. The thermal module 102 is a double-sided thermal module providing thermal dissipation paths for a top side and a bottom side of the package. The thermal module 102 comprises a “sandwich” style thermal module component having a top plate 104 and a bottom plate 106. It is noted that in comparison to the embodiment of the package 100, discussed above with reference to FIG. 1, the package 600 omits an additional liquid cooling system such as liquid cooling system 108.

The package 600 includes a substrate 112 upon which integrated circuit die 110 are disposed. In an embodiment, a plurality of chiplets 114 may be provided on the substrate 112. In some implementations, various components including die and/or VRM components are provided on a backside of the substrate 112. One or more rings 116 are provided at the edge of the substrate 112 including as discussed above with reference to the package 100.

The thermal module 102 comprises a “sandwich” style thermal module component having a top plate 104 and a bottom plate 106, between which the substrate 112 and IC die 110 are disposed. In some implementations, the top plate 104 and the bottom plate 106 are referred to as cold plates. In some implementations, the sandwich style thermal module component including the bottom plate 106 provides a heat dissipation path for integrated circuit die 110 and/or VRM components attached to a bottom side of the substrate 112 (see FIG. 6B) by being thermally coupled to said components. In some implementations, the sandwich style thermal module component including the top plate 104 provides a heat dissipation path for integrated circuit die 110 attached to a top side of the substrate 112 by being thermally coupled to said components.

The top plate 104 and the bottom plate 106 are connected by heat pipes 118. The heat pipes 118 are U-shaped heat pipes extending from the top plate 104 to the bottom plate 106. Four heat pipes 118 are illustrated on each end of the package 100, however any number of heat pipes 118 may be included. The heat plates 104 and 106 may be comprised of metal. In an embodiment, the heat plates 104 and 106 are comprised of a metal suitable for conducting heat such as aluminum, copper, gold, or the like. In an embodiment, one or more of the heat plates 104 and 106 are filled with liquid. In some implementations, the liquid of the heat plates 104 and/or 106 may be substantially similar to the liquid of the liquid cooling system 108, discussed below. The liquid may be comprised of a material selected for its high enthalpy of vaporization.

The thermal module 102 secures the top plate 104 and the bottom plate 106 using a fastening mechanism 120. The fastening mechanism 120 may be a spring screw. Four fastening mechanisms 120 are illustrated in FIG. 6A, however, other configurations and number of fasteners may be provided. The fastening mechanisms 120 serve to clamp the thermal module into its sandwich configuration. The fastening mechanisms 120, such as a spring screw, may provide a suitable force to sandwich the thermal module (and plates 104/106) thereby providing thermal coupling and/or physical contact of the IC die 110, directly or through thermal interface material (TIM) (illustrated below in FIG. 6B) disposed on the IC die 110, with the plate 104. In an embodiment, as illustrated in package 600 in FIG. 6B, a gap is provided between the frontside ring 116 disposed on a top surface of the substrate 112 and the plate 104.

The fastening mechanisms 120, such as a spring screw, may provide a suitable force to sandwich the thermal module (and plates 104/106) thereby providing thermal coupling and/or physical contact of the VRM 204, directly or through thermal interface material (TIM) (illustrated below in FIG. 6B) disposed on the VRM 204, with the plate 106. In an embodiment as illustrated in FIG. 6B, the VRM 204 of the package 600 are connected to the bottom plate 106 using TIM 220 between the bottom surface of the VRM 204 and the bottom plate 106. In some implementations, the TIM 220 may have an edge substantially aligned with the VRM 204.

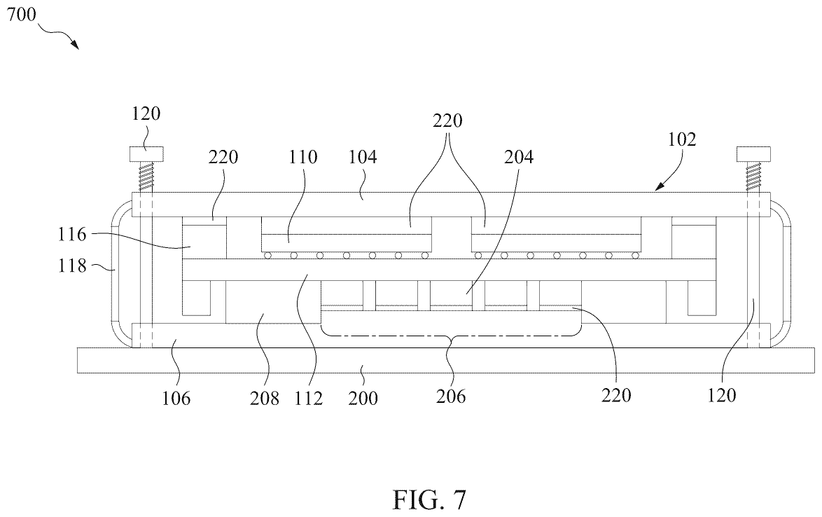

Referring to FIG. 7, illustrated is a cross-sectional view of another semiconductor device package 700 including a thermal module according to one or more aspects of the present disclosure. The package 700 is substantially similar to the packages 600, 100″, 100′ and/or 100 discussed above. Similar to as discussed above, the package 700 includes a thermal module 102. The thermal module 102 is a double-sided thermal module providing thermal dissipation to a top side and a bottom side of the package. The thermal module 102 comprises a “sandwich” style thermal module component having a top plate 104 and a bottom plate 106. It is noted that in comparison to the embodiment of the package 100, discussed above with reference to FIG. 1, the package 700 omits an additional liquid cooling system such as liquid cooling system 108. It is noted that in comparison to the embodiment of the package 600, discussed above with reference to FIG. 6, the package 700 applies TIM 220 between the frontside ring 116 and the top plate 104. The TIM 220 may assist in transferring heat from the frontside ring 116 to the top plate 104, where it can be further dissipated. In an embodiment, a thickness of the TIM 220 over the IC die 110 is greater than a thickness of the TIM over the frontside ring 116.

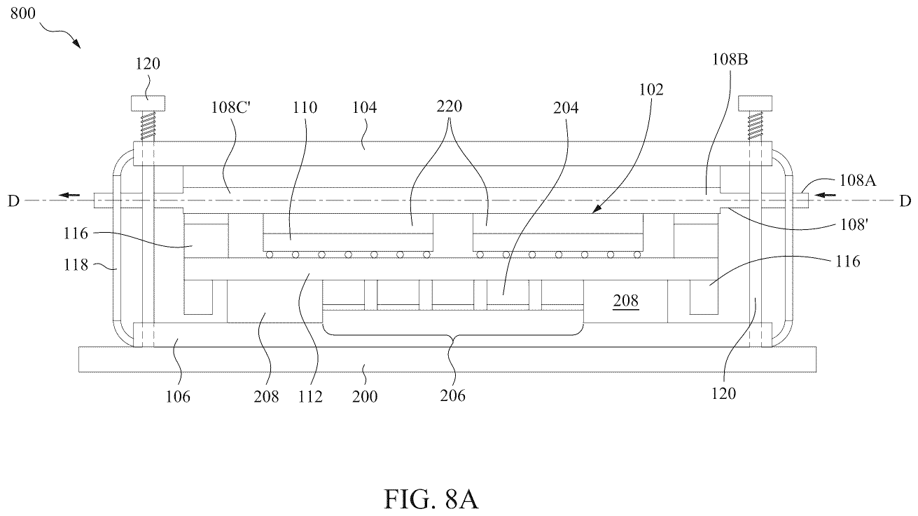

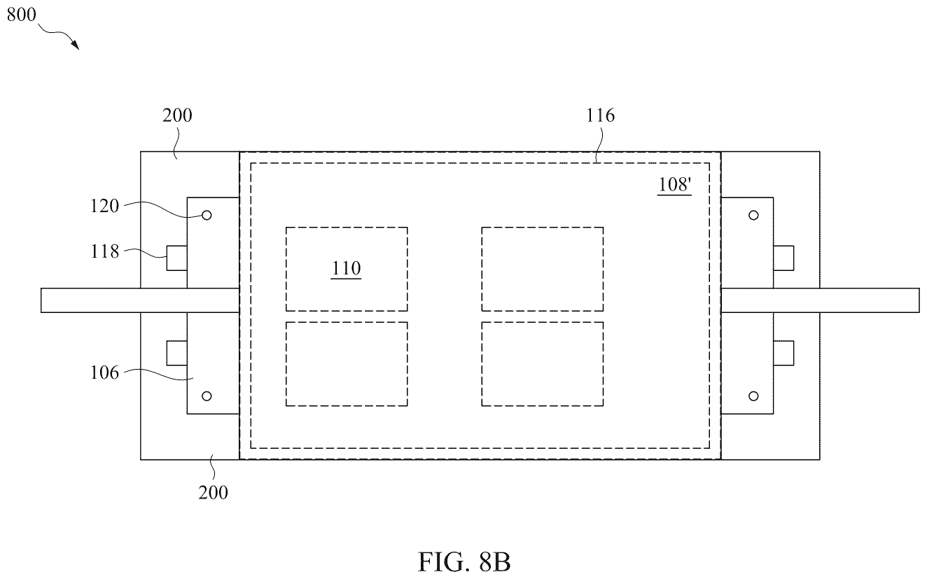

Referring to FIG. 8A, illustrated is a cross-sectional view of another semiconductor device package 800 including a thermal module according to one or more aspects of the present disclosure. The package 800 is substantially similar to the packages 700, 600, 100″, 100′ and/or 100 discussed above. Similar to as discussed above, the package 800 includes a thermal module 102. The thermal module 102 is a double-sided thermal module providing thermal dissipation to a top side and a bottom side of the package. The thermal module 102 comprises a “sandwich” style thermal module component having a top plate 104 and a bottom plate 106. Similar to the embodiment of the package 100, discussed above with reference to FIG. 1, the package 800 includes an additional liquid cooling system, illustrated in FIG. 8A as liquid cooling system 108′. The liquid cooling system 108′ is substantially similar to the liquid cooling system 108 discussed above with differences noted herein.

The liquid cooling system 108′ brings additional heat dissipation from a top-side of the package 800. In an implementation, the liquid cooling system 108′ serves to dissipate heat from the integrated circuit die 110. In an implementation, the liquid cooling system 108′ serves to dissipate heat from the upper plate 104. Similar to the liquid cooling system 108 discussed above, the liquid cooling system 108′ includes an inlet 108A, an outlet 108B for a coolant, and a center portion 108C′ having a passage for the coolant disposed therein.

The center portion 108C′ of the liquid cooling system 108′ is of a size such that it extends over each of the IC die 110. In some implementations, the liquid cooling system 108′ is of sufficient size to extend over the frontside ring 116. The liquid cooling system 108′ may be attached (e.g., physically and thermally coupled) to the IC dies 110 and the frontside ring 116 directly or through TIM 220. In some implementations, a terminal edge of the center portion 108C′ aligns with an outer terminal edge of the frontside ring 116.

Thus, provided are a plurality of embodiments of a package having a thermal module that provides heat dissipation paths traversing the lower side and upper side of the package. The thermal module is thermally coupled to components (e.g., IC die, VRM, etc.) mounted on multiple sides of a substrate of a semiconductor device. The module provides a lower plate thermally coupled to components on a lower surface of the semiconductor device substrate, and an upper plate thermally coupled to components on an upper surface of the semiconductor substrate. Thermal pipes and/or liquid cooling systems serve to dissipate heat from the plates of the thermal module.

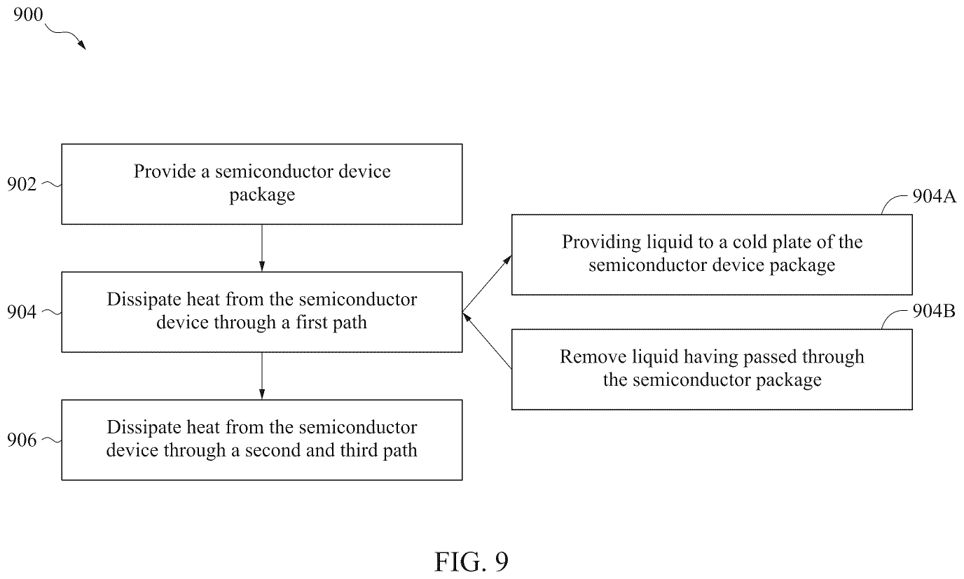

FIG. 9 illustrates a flow chart of a method 900 for dissipating heat from a surroundings of an IC device. In an embodiment, the method 900 is implemented by using the thermal modules such as the sandwich type module 102 discussed above and is used to dissipate heat in semiconductor device packages, such as the package 100 discussed above with reference to FIG. 1.

The method 900 begins at block 902 where a semiconductor device package is provided. The semiconductor device package may be substantially similar to the packages 100, 100′, 100″, 600, 700, and/or 800 discussed above. The semiconductor device package may include one or more IC die or chips mounted on a substrate. In an embodiment, the package further includes IC die of a VRM. The IC die may be mounted on a top surface and a bottom surface of a substrate. The semiconductor device package also includes a thermal module for dissipating heat from said IC die and/or VRM including those die on the top and the bottom surfaces of the substrate. The thermal module may include an upper and lower plate forming a sandwich-style thermal module such as the module 102 and the plates 104 and 106 discussed above. The package may in some implementations further include a liquid cooling plate disposed within the sandwich-style thermal module (e.g., between the upper and lower plates). The liquid cooling plate may be substantially similar to the liquid cooling plate 108 and/or 108′ discussed above.

In block 904 of the method 900 heat is dissipated from an IC die of the semiconductor device through a first path. The heat may be dissipated from an IC die including and/or a VRM or other component of the semiconductor device. In an embodiment, the first path for dissipating heat includes using a liquid cooling plate that is thermally coupled to the semiconductor device (e.g., IC die). As discussed above, liquid cooling plate 108 and/or 108′ are exemplary components providing a first path or mechanism for dissipating heat. In an embodiment, block 804 includes providing a coolant liquid to a liquid cooling plate (block 904A), providing the liquid through a passage in the plate to an outlet, and removing the coolant liquid from the semiconductor device package (block 904B). Heat may be dissipated from the semiconductor device (e.g., IC die 110 and/or VRM 204) of the semiconductor package by dispersion of the heat from the device to the liquid cooling plate and the coolant contained therein. In some embodiments, block 904 is omitted.

In block 906 of the method 900 heat is dissipated from the semiconductor device through a second path and a third path. In some implementations, the second path is provided from an upper surface of a semiconductor device such as an upper surface of a substrate having a plurality of die disposed thereon, and the third path is provided from a lower surface of the semiconductor device such as a lower surface of the substrate having a plurality of die disposed thereon. In other words, the second and third path begin in opposing directions. Block 906 may occur concurrently with block 904.

In an implementation, block 906 is performed by a thermal module having a sandwich-type configuration with an upper plate and lower plate. The thermal module is suitable to provide a double-sided thermal path—a second path and a third path—for heat to dissipate away from semiconductor devices (e.g., IC die and/or VRM components) in the semiconductor package. For example, in an embodiment, an upper plate is thermally coupled to semiconductor devices on an upper surface of a substrate, and the bottom plate is thermally coupled to semiconductor devices on a lower surface of a substrate (such as a VRM module) so as to provide two thermal dissipation paths. The heat pipes connect the upper and lower plates to provide thermal cycling within plates and dissipate the heat from plates. In some implementations, the thermal coupling between the semiconductor devices and the plates are provided through TIM. In some implementations, the thermal coupling between the semiconductor devices with a plate of the module is provided through the liquid cooling system.

The disclosure provides for several embodiments of thermal modules that allow for multiple thermal paths to dissipate heat from semiconductor devices-including from components disposed on both the front surface and the back surface of a substrate of the device. The semiconductor device packages discussed herein are described as providing a thermal module for a semiconductor device having a substrate with a plurality of IC die on an upper surface and a plurality of VRM on a lower surface. However, it should be clearly appreciated the sandwich-style thermal module may be applied to various semiconductor devices. That is, between the upper plate and the lower plate of the thermal module any variation of semiconductor structure may be provided that would benefit from multiple heat dissipation paths.

Thus, one of the embodiments of the present disclosure described a semiconductor device including a substrate having one or more integrated circuit die disposed on a top surface and a thermal module surrounding the substrate. The thermal module includes: an upper plate, a lower plate, wherein the substrate is positioned between the upper plate and the lower plate, and at least one heat pipe extending from the upper plate to the lower plate.

In some implementations, the device also includes a plurality of voltage regulator modules (VRM) disposed on a bottom surface of the substrate. A thermal interface material (TIM) may extend from each of the plurality of VRM to the lower plate. In an embodiment, a liquid cooling plate between the upper plate and the one or more integrated circuit die. In a further embodiment, the liquid cooling plate includes an inlet for a coolant and an outlet for the coolant. In an embodiment, a first thermal interface material (TIM) extending from the liquid cooling plate to an upper surface of the integrated circuit die and a second TIM extending from the liquid cooling plate the upper plate.

In some implementations of the device, a spring screw coupling the upper plate and the lower plate. In an embodiment, the upper plate and the lower plate are filled with a liquid. In some implementations, the device also includes an frontside ring extending along an upper surface of a periphery of the substrate and a backside ring extending along a lower surface of the periphery of the substrate. The frontside ring and the backside ring may be between the upper plate and the lower plate.

In another of the embodiments, discussed is a semiconductor device including a substrate having a top surface and a bottom surface, an integrated circuit (IC) die disposed on the top surface, a voltage regulator module (VRM) disposed on the bottom surface, an upper thermally conductive plate disposed over the top surface of the substrate and thermally coupled to the IC die, a lower thermally conductive plate disposed under the lower surface of the substrate and thermally coupled to the VRM and a connection extending between the upper thermally conductive plate and the lower thermally conductive plate.

In an embodiment, the connection is a plurality of heat pipes. In an embodiment, the connection is a spring screw. In some implementations, a liquid cooling plate is disposed between the top surface of the substate and the upper thermally conductive plate. In an embodiment, a thermal interface material extend from the VRM to the lower thermally conductive plate. In an implementation, the lower thermally conductive plate includes a raised portion adjacent the VRM. In some implementations, IC die is a chip disposed on a substrate such as a chip-on-wafer.

In another of the embodiments, discussed is a method for forming a semiconductor device including assembling a thermal component for a semiconductor device package. The method may include providing a substrate having at least on integrated circuit (IC) and positioning an upper plate above the substrate. A lower plate is positioned below the substrate. The upper plate and the lower plate are attached by at least one of thermal pipes or a spring screw.

In some implementations, prior to positioning the upper plate, the method includes providing a liquid cooling plate over the substrate. The positioning the upper plate includes positioning the upper plate is above the liquid cooling plate. The method may also include connecting an outlet of the liquid cooling plate to another liquid cooling plate of another package. In an embodiment, the method includes disposing thermal interface material between the IC die and the upper plate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate having a first integrated circuit die and a second integrated circuit die disposed on a top surface;
a thermal interface material (TIM) extending from an upper surface of the first integrated circuit die to a liquid cooling system and from an upper surface of the second integrated circuit die to the liquid cooling system;
the liquid cooling system including a plate portion, an inlet and an outlet, wherein the TIM interfaces a bottom surface of the plate portion;
another TIM extending from an upper surface of the plate portion to an upper plate of a thermal module;
the thermal module surrounding the substrate, wherein the thermal module includes:
the upper plate, and
a lower plate, wherein the substrate is positioned between the upper plate and the lower plate; and
a plurality of voltage regulator modules (VRM) disposed on a bottom surface of the substrate.

2. The device of claim 1, further comprising:
a ring disposed on the top surface of the substrate.

3. The device of claim 2, wherein a third TIM extends from the ring to the bottom surface of the plate portion.

4. The device of claim 2, further comprising:
another ring disposed on the bottom surface of the substrate, wherein the VRM interpose a first portion of the another ring and a second portion of the another ring.

5. The device of claim 4, wherein the inlet and the outlet are disposed outside of the another ring in a cross-sectional view.

6. The device of claim 1, wherein the lower plate includes a raised portion.

7. The device of claim 6, wherein the VRM are disposed on the raised portion of the lower plate.

8. The device of claim 7, wherein a third TIM interposes VRM and the raised portion.

9. The device of claim 1, further comprising: a spring screw coupling the upper plate and the lower plate.

10. The device of claim 1, further comprising:
a connector material surrounding the VRM and interfacing the bottom surface of the substrate.

11. A device comprising:
a substrate having a top surface and a bottom surface;
a plurality of integrated circuit (IC) die disposed on the top surface;
a plurality of voltage regulator module (VRM) disposed on the bottom surface; and
a connector material interfacing the bottom surface and surrounding the plurality of VRM.

12. The device of claim 11, further comprising:
a first ring disposed on the top surface; and
a second ring disposed on the bottom surface.

13. The device of claim 12, wherein the connector material has a first thickness and the second ring disposed on the bottom surface has a second thickness, the first thickness greater than the second thickness.

14. The device of claim 11, further comprising:
an upper thermally conductive plate disposed over the top surface of the substrate and thermally coupled to the IC die; and
a lower thermally conductive plate disposed under the bottom surface of the substrate and thermally coupled to the VRM.

15. The device of claim 14, further comprising:
a spring screw extending between the upper thermally conductive plate and the lower thermally conductive plate.

16. The device of claim 14, wherein the plurality of VRM directly interface the bottom surface and a thermal interface material extends from the VRM to the lower thermally conductive plate.

17. The device of claim 14, further comprising:
a liquid cooling plate between the upper thermally conductive plate and the substrate.

18. A method of assembling a thermal component for a semiconductor device package, the method comprising:
providing a substrate having at least one integrated circuit (IC) on a top surface;
providing a plurality of voltage regulator module (VRM) on a bottom surface of the substrate;
positioning a lower plate below the substrate and thermally connected to the plurality of VRM; and
positioning an upper plate above the substrate.

19. The method of claim 18, further comprising:
prior to positioning the upper plate, providing a liquid cooling plate over the substrate; and
sending a coolant through the liquid cooling plate.

20. The method of claim 19, further comprising:
thermally connecting the at least one IC and the liquid cooling plate by thermal interface material (TIM).
